(19) United States
(12) Patent Application Publication
(10) Pub. No.: US 2026/0047337 A1
(43) Pub. Date: Feb. 12, 2026

(54) MANAGING 2D/3D HETEROSTRUCTURE ENERGY LANDSCAPE VIA PI-CONJUGATED ORGANIC CATIONS FOR EFFICIENT PEROVSKITE SOLAR CELLS

(71) Applicant: Purdue Research Foundation, West Lafayette, IN (US)

(72) Inventors: Letian Dou, West Lafayette, IN (US); Jiaonan Sun, West Lafayette, IN (US); Ke Ma, West Lafayette, IN (US)

(21) Appl. No.: 19/359,180

(22) Filed: Oct. 15, 2025

Related U.S. Application Data
(63) Continuation of application No. 18/483,875, filed on Oct. 10, 2023.
(60) Provisional application No. 63/427,650, filed on Nov. 23, 2022.
(60) Provisional application No. 63/506,801, filed on Jun. 7, 2023.

(51) Int. Cl. H10K 85/50; H10K 30/10; H10K 30/20; H10K 30/50; H10K 30/81; H10K 30/86; H10K 71/12; H10K 71/40; H10K 71/60; H10K 102/20

(52) U.S. Cl. CPC H10K 85/50; H10K 30/50; H10K 30/81; H10K 30/86; H10K 71/12; H10K 71/40; H10K 71/60; H10K 30/10; H10K 30/20; H10K 2102/20

(57) ABSTRACT

A device and a photovoltaic device, both of which include a 3D perovskite layer and an organic 2D perovskite layer operationally connected to the 3D perovskite layer and defining a heterojunction interface. The photovoltaic device further includes an electrode layer, a hole transport layer operationally connected to and sandwiched between the electrode layer and the organic 2D perovskite layer, a substrate layer, and a tin oxide layer operationally connected to and sandwiched between the substrate layer and the 3D perovskite layer. Also provided is a method of making the photovoltaic device.

### CROSS-REFERENCE TO RELATED APPLICATIONS

This patent application is a continuation of U.S. patent application Ser. No. 18/483,875, filed on Oct. 10, 2023, which claims the benefit under 35 U.S.C § 119(e) of U.S. Patent Application 63/427,650, filed on 23 Nov. 2022, and of U.S. Patent Application 63/506,801, filed on 7 Jun. 2023, each of which is incorporated by reference herein in its entirety.

### GOVERNMENT FUNDING

This invention was made with government support under DE-EE0009519 awarded by the Department of Energy. The government has certain rights in the invention.

### BACKGROUND

Perovskite solar cells (PSCs) have emerged as a strong candidate for future photovoltaic technology. However, achieving high efficiency together with long-term stability is still a challenge. More recently, the strategy of constructing two-dimensional/three-dimensional (2D/3D) heterostructures to passivate interface defects and improve stability has contributed to some of high-efficiency devices, including the high-performance PSC. These studies have also revealed that energy level alignment at the 2D/3D heterojunction is preferred for efficient charge transfer. However, the methods of managing energy level alignment are limited to phase control of 2D perovskites (i.e., the thickness of the inorganic layers), owing to the insignificant contribution of conventional organic ligands to the density of states at the band edges in 2D perovskites. Interfacial losses persist as well. Thus, there remains a need for an improved 2D/3D heterojunction PSC. The present disclosure addresses this need.

### SUMMARY

Molecular engineering was used to manipulate the energy landscapes at heterojunctions to achieve efficient and stable perovskite solar cells. Constructing a two-dimensional (2D) perovskite layer heterojoined to a 3D perovskite structure with controlled energy landscape management is still a challenge in perovskite solar cells. Herein, a strategy is disclosed including designing a series of π-conjugated organic cations to construct stable 2D perovskites, and to realize the delicate energy level tunability at 2D/3D heterojunctions. As a result, the hole transfer energy barriers can be reduced both at heterojunctions and within the 2D structures, and the preferrable work function shift reduces the charge accumulation at interface. Leveraging these tools, and also benefitting from the superior interface contact between conjugated cations and the poly(triarylamine) (PTAA) hole transporting layer, a solar cell with power conversion efficiency of 24.6% has been achieved, offering exceptional power conversion efficiency, even among PTAA-based n-i-p devices. The instant devices also exhibit greatly enhanced stability and reproducibility. Fortuitously, this approach is generic to several small molecular and polymeric hole transporting materials, offering opportunities to realize high efficiency without using the unstable Spiro-OMeTAD.

### BRIEF DESCRIPTION OF THE DRAWINGS

FIGS. 1A-IC graphically illustrate a photovoltaic device structure according to a first embodiment of the present novel technology, including a 3D perovskite thin film layer and a 2D organic perovskite layer operationally connected thereto.

FIGS. 2A-2F graphically illustrate the structure of the organic 2D perovskite monolayer of FIGS. 1A-1C.

FIGS. 3A-3D graphically illustrate the heterojunction between the 3D perovskite film and the organic 2D perovskite monolayer of FIGS. 1A-1C.

FIGS. 4A-4G graphically illustrate some performance characteristics of the device of FIGS. 1A-1C.

### DETAILED DESCRIPTION

For the purposes of promoting an understanding of the principles of the disclosure, reference will now be made to the embodiments illustrated in the drawings and specific language will be used to describe the same. It will nevertheless be understood that no limitation of the scope of the disclosure is thereby intended, such alterations and further modifications in the illustrated device, and such further applications of the principles of the disclosure as illustrated therein being contemplated as would normally occur to one skilled in the art to which the disclosure relates. At least one embodiment of the present disclosure will be described and shown, and this application may show and/or describe other embodiments of the present disclosure. It is understood that any reference to “the disclosure” is a reference to an embodiment of a family of disclosures, with no single embodiment including an apparatus, process, or composition that should be included in all embodiments, unless otherwise stated. Further, although there may be discussion with regards to “advantages” provided by some embodiments of the present disclosure, it is understood that yet other embodiments may not include those same advantages, or may include yet different advantages. Any advantages described herein are not to be construed as limiting to any of the claims. The usage of words indicating preference, such as “preferably,” refers to features and aspects that are present in at least one embodiment, but which are optional for some embodiments.

Although various specific quantities (spatial dimensions, temperatures, pressures, times, force, resistance, current, voltage, concentrations, wavelengths, frequencies, heat transfer coefficients, dimensionless parameters, etc.) may be stated herein, such specific quantities are presented as examples only, and further, unless otherwise explicitly noted, are approximate values, and should be considered as if the word “about” prefaced each quantity. Further, with discussion pertaining to a specific composition of matter, that description is by example only, and does not limit the applicability of other species of that composition, nor does it limit the applicability of other compositions unrelated to the cited composition.

What will be shown and described herein, along with various embodiments of the present disclosure, is discussion of one or more tests that were performed. It is understood that such examples are by way of example only and are not to be construed as being limitations on any embodiment of the present disclosure. Further, it is understood that embodiments of the present disclosure are not necessarily limited to or described by the mathematical analysis presented herein.

Various references may be made to one or more processes, algorithms, operational methods, or logic, accompanied by a diagram showing such organized in a particular sequence. It is understood that the order of such a sequence is by example only, and is not intended to be limiting on any embodiment of the disclosure.

This document may use different words to describe the same element number, or to refer to an element number in a specific family of features. It is understood that such multiple usage is not intended to provide a redefinition of any language herein. It is understood that such words demonstrate that the particular feature can be considered in various linguistical ways, such ways not necessarily being additive or exclusive.

What will be shown and described herein are one or more functional relationships among variables. Specific nomenclature for the variables may be provided, although some relationships may include variables that will be recognized by persons of ordinary skill in the art for their meaning. For example, “t” could be representative of temperature or time, as would be readily apparent by their usage. However, it is further recognized that such functional relationships can be expressed in a variety of equivalents using standard techniques of mathematical analysis (for instance, the relationship F=ma is equivalent to the relationship F/a=m). Further, in those embodiments in which functional relationships are implemented in an algorithm or computer software, it is understood that an algorithm-implemented variable can correspond to a variable shown herein, with this correspondence including a scaling factor, control system gain, noise filter, or the like.

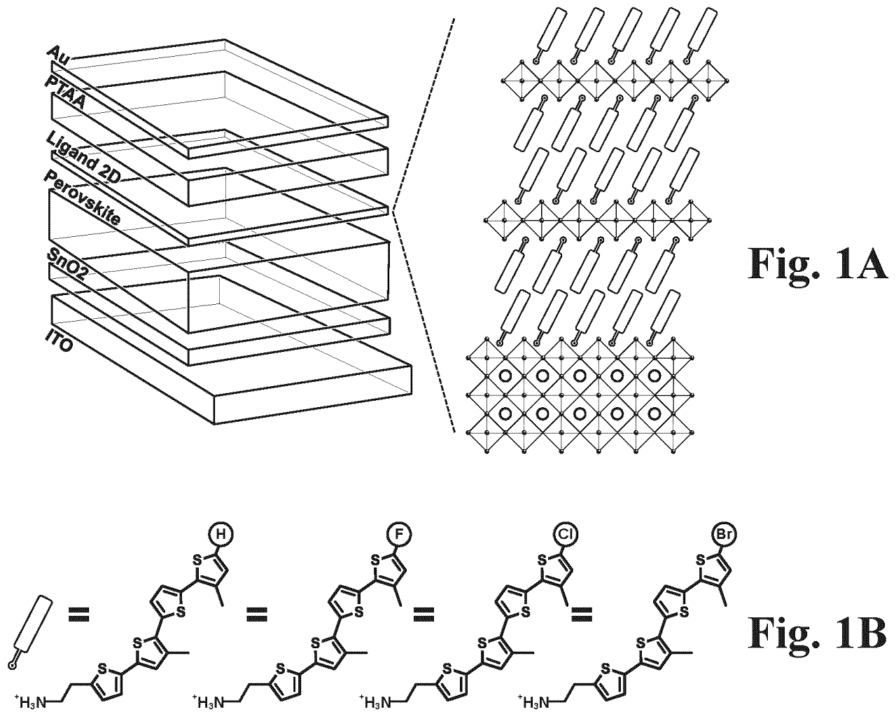

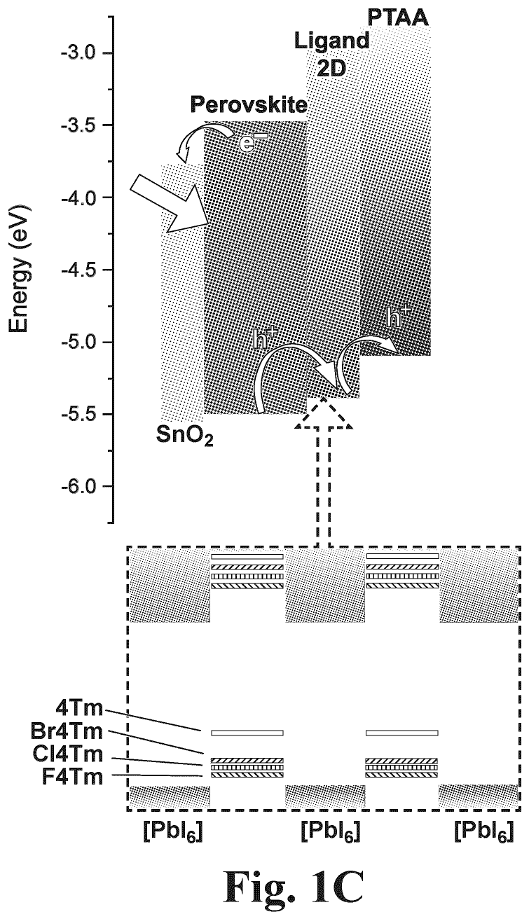

FIGS. 1A-4G illustrate a series of bulky semiconducting ligands with tunable energy levels that define stable 2D perovskites (FIG. 1A). While not being two-dimensional in the strictest sense, 2D perovskites are commonly defined as having one octahedral layer separated by spacer cations, while quasi-2D perovskites are obtained when n octahedral layers are separated by organic cations, with n being an integer greater than one. These π-conjugated ligands provide an opportunity for manipulating energy level alignment at a 2D/3D heterojunctions through rational design of organic cations, thereby allowing more efficient hole extraction and reducing interface charge accumulation. Furthermore, the reduced energy level offset between the valence band maximum (VBM) of inorganic sheets and the highest occupied molecular orbital (HOMO) of conjugated organic layers in 2D perovskites, and preferable ligand packing geometry, allow more efficient hole transfer through the out-of-plane direction. This holistic energy landscape management of the 2D/3D heterojunction in PSCs, together with the improved interface quality between perovskite and polymeric hole transporting layer (HTL) via π-conjugated ligands, enabled the demonstration of a remarkable power conversion efficiency (PCE) of 24.6% for poly(triarylamine) (PTAA)-based devices with n-i-p structure. The fine-tuned conjugated ligands allow for a more stable 2D structure and suppress interlayer ion migration, which yield improved photostability and thermal stability.

### 2D Perovskite Structures and Properties

One strategy regarding the ligands is tethering an ammonium anchoring group to one end of an synthesized organic 2D ligand, such as a conjugated quaterthiophene unit, and having halogen substitution on the opposite end thiophene to manipulate the highest occupied molecular orbital (HOMO) levels of the molecules. The chemical structures of the synthesized organic ligands feature different substituting groups, namely F4TmI, Cl4TmI, Br4TmI, all of which are derived from 4TmI (FIG. 1B). The synthesis of halogen-4Tm was based on electrophilic halogenation reactions to add functional groups, and a Stille-coupling reaction to connect all the thiophene moieties together. All ligands were converted to iodide salts through reactions with hydroiodic acid. The halogen-substituent acts as an electron-withdrawing group that deepens the HOMO level of the ligands, from −5.21 eV for 4Tm, to −5.25 eV, −5.26 eV and −5.25 eV, for F4Tm, Cl4Tm and B4Tm ligands, respectively.

Within the 2D perovskite, or generally flat monolayer structures formed with these ligands, type-II band alignments are formed, due to the small bandgaps and shallow HOMO levels of the conjugated ligands (FIG. 1C). The type-II alignment results in quenched photoluminescence observed from these 2D perovskite thin films. Unlike the conventional wide-bandgap ligands which usually form type-I artificial quantum wells in 2D perovskites and generate energy barriers for out-of-plane charge transfer, the shallow HOMO levels of conjugated ligands reduce the energy barriers for hole transfer. However, the shallow HOMO level of 4Tm creates a reverse energy level offset with inorganic layers in 2D perovskites, which in turn can potentially trap holes. The halogen-4Tm reduces the energy level offsets, suggesting minimal energy barriers and a decreased probability of hole trapping, which in principle could facilitate out-of-plane hole transport within 2D perovskite structures.

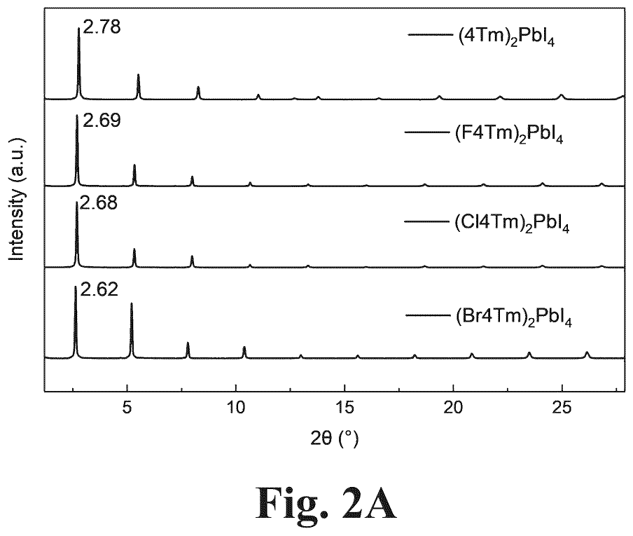

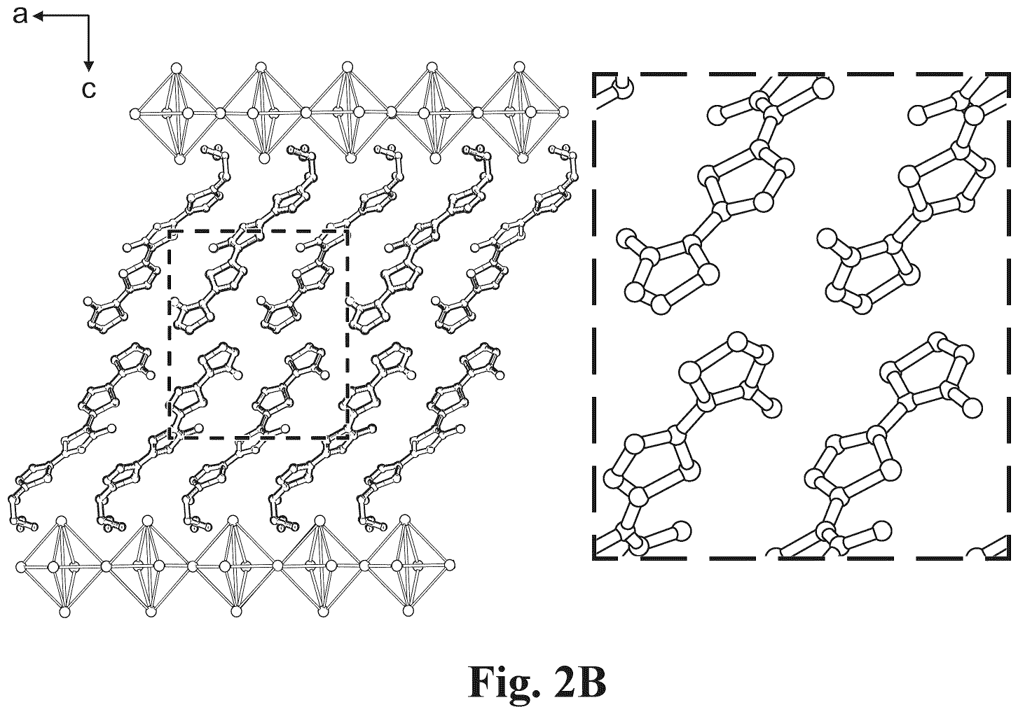

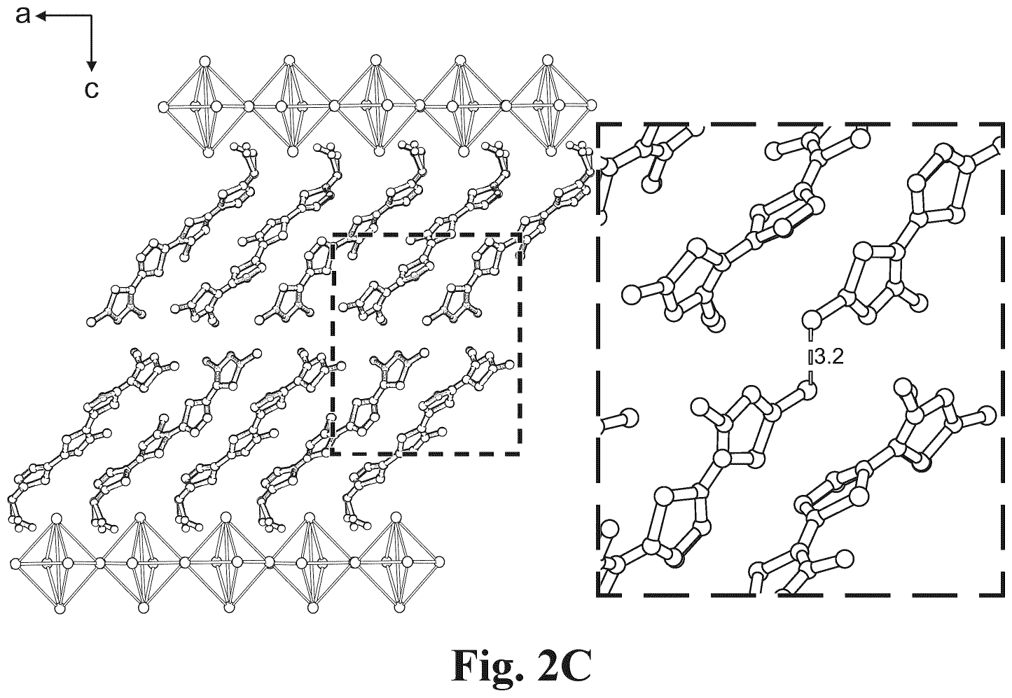

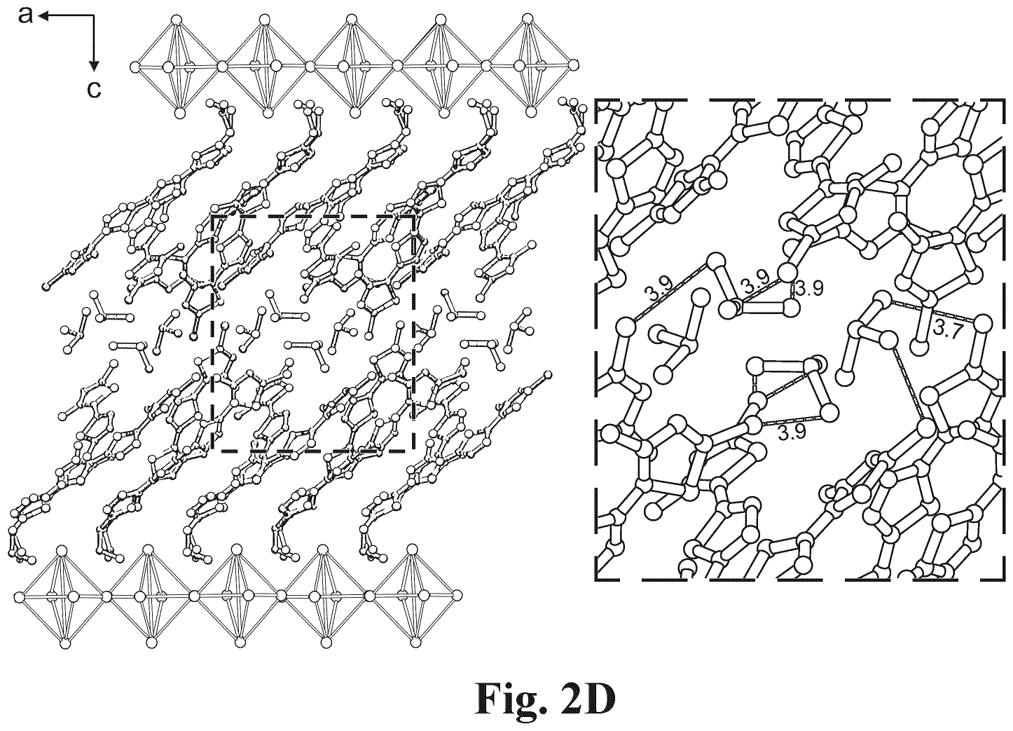

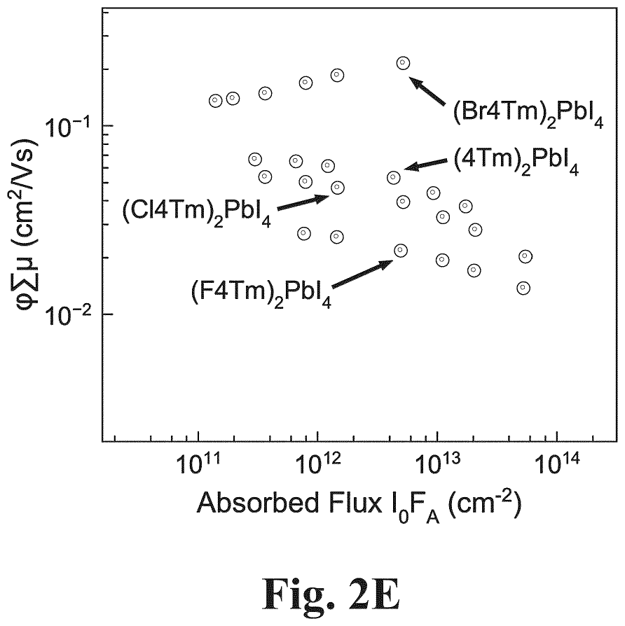

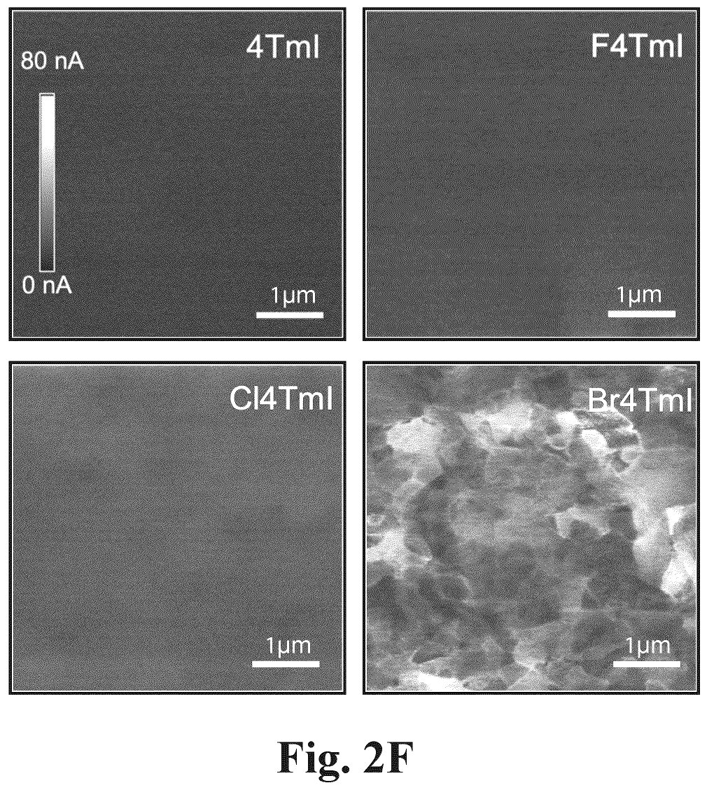

Beside the energy level alignment, a strong dependence between crystal structures and electronic properties also exists in 2D perovskites. Therefore, we characterized 2D perovskites through thin film X-ray diffraction (XRD) and single crystal analysis to gain insights from their crystal structures. The 2D perovskite thin films can be obtained by one-step spin coating followed by thermal annealing. The XRD patterns with characteristic planes—(001), (002), (003), etc., are different from the XRD patterns of the aggregated ligands, confirming the formation of layered 2D structures (FIG. 2A). The absorption spectra exhibited distinctive exitonic peaks at around 512 nm, further supporting the formation of n=1 2D Ruddlesden-Popper (RP) phase perovskites. The corresponding d-spacings of (4Tm)2PbI4, (F4Tm)2PbI4, (Cl4Tm)2PbI4 and (Br4Tm)2PbI4 were calculated as 3.18, 3.28, 3.28, and 3.37 nm from the 2θ of (001) planes at 2.78°, 2.69°, 2.68° and 2.62°, respectively, which is correlated with the increased atomic radius of H, F, Cl and Br. It is important to note that even though fluorine has a smaller atomic radius than chlorine, (F4Tm)2PbI4 and (Cl4Tm)2PbI4 share similar interlayer distances, which is likely due to the interplay between atomic vs. electrostatic attractive and repulsive forces.

To gauge the effect of molecular configuration on the intermolecular packing, we further examined the single crystals of 2D perovskites formed with different ligands (FIGS. 2B, 2C and 2D). Single crystals of (Cl4Tm)2PbI4 were obtained by slow-cooling method, while solvent diffusion method was applied to grow crystals of the general configuration (X₄Tm)₂PbI₄, and in this particular example (Br₄Tm)₂PbI₄, wherein in general X may be F, CL, Br, and the like and the number of thiophene rings may be from two to six. In addition to halogens, ‘X” may include —H, —I, —CN, —SCN, —OCN, —CF3, —CH3, —OH, —SH, —OCH3, —SCH3, —COOH and —CH₂CH₃. For F4Tm, suitable crystal specimens for accurate single crystal structure determination proved challenging and resulted in high R-factors, even though several attempts have been made, which is probably due to the weak interactions between F4Tm layers (FIG. S5). The average in-plane Pb—I—Pb bond angle is 151.6° and the Pb—I bond length is 3.17 Å (horizontal). Interestingly, we observed a small distance of 3.2 Å between alternating Cl—Cl atoms within two Cl₄Tm layers, which indicates the existence of weak halogen interaction (considering the 1.75 Å van der Waals radius of a single chlorine atom) and could contribute to the stabilization of the structure. (Br₄Tm)₂PbI₄ single crystal structure was resolved with chloroform solvent molecules trapped between the ligand layers, from which Br—Cl halogen interaction between Br4Tm and chloroform were observed due to the shortened inter-atom distance. Because of solvent intercalation, the inorganic lattice of (Br4Tm)2PbI4 has less distortion compared with (Cl₄Tm)₂PbI₄, with an average in-plane Pb—I—Pb bond angle as 152.6° and Pb—I bond length as 3.14 Å (horizontal). However, part of the conjugated ligand molecules in (Br4Tm)2PbI4 crystal structure exhibit more distortion compared to (Cl₄Tm)₂PbI4, which could increase the formation barrier of this 2D structure.

### EXAMPLES

### 3,3″-Dimethyl-2,2′:5′,2″-terthiophene

2,5-bis(tributylstannyl)thiophene (2.6 g, 7.8 mmol), 2-bromo-3-methylthiophene (1.4 g, 3.9 mmol), tris(dibenzylideneacetone)dipalladium (72 mg, 0.078 mmol, 2%) and tri(o-tolyl)phosphine (95 mg, 0.31 mmol, 8%) was mixed and then degassed three times. 60 ml dry toluene was added via syringe and the mixture was stirred at 60° C. for 4 hours. After the reaction was cooled to room temperature, water was added. Diethyl ether was used to extract the product in a separatory funnel three times and the organic phase was further washed with brine. All the organic layers were combined and dried with magnesium sulfate. After filtration, the solvent was removed by rotary evaporation and the crude product was further purified by silica column with pure hexane. In the end, 0.79 g of light-yellow solid was obtained in a yield of 71%. 1H NMR (400 MHz, CDCl3) δ 7.15 (d, J=5.1 Hz, 2H), 7.08 (s, 2H), 6.89 (d, J=5.0 Hz, 2H), 2.42 (s, 6H).

### 5-Fluoro-3,3″-dimethyl-2,2′:5′,2″-terthiophene

To a solution of (7.2 mmol, 2 g) dissolved in 112 ml dry THF, 2.5 M n-butyl lithium (7.4 mmol, 3 ml) was added dropwise via syringe at −78° C. in dry ice/acetone bath in argon environment. Then the dry ice was removed, and the mixture was stirred for 1.5 hour during warm up. The mixture was then cooled to −78° C. again and N-fluorobenzenesulfonimide (NFSI, 7.9 mmol, 2.5 g) dissolved in 10 ml dry THF was added to the reaction mixture. The reaction was then stirred at room temperature overnight and water was added to quench the reaction. Dichloromethane was used to extract the product in a separatory funnel three times and the organic phase was further washed with brine. All the organic layers were combined and dried with magnesium sulfate. The solvent was removed by rotary evaporation and the crude product was further purified by column chromatography with pure hexane. 1.1 g yellow solid was obtained in a yield of 53%. 1H NMR (400 MHz, CDCl3) δ 7.15 (d, J=5.1 Hz, 1H), 7.05 (d, J=3.8 Hz, 1H), 6.98 (d, J=3.8 Hz, 1H), 6.91-6.84 (m, 1H), 6.30 (d, J=2.3 Hz, 1H), 2.41 (s, 3H), 2.31 (s, 3H).

### Tributyl(5″-fluoro-3,3″-dimethyl-[2,2′:5′,2″-terthiophen]-5-yl)stannane

To a solution of (1.5 mmol, 447 mg) dissolved in 16 ml dry THF, 2.0 M lithium diisopropylamide in hexane (1.67 mmol, 0.84 ml) was added dropwise via syringe at 0° C. in ice bath. Then the ice bath was removed, and the mixture was stirred for 1.5 hour during warm up. The mixture was then cooled to 0° C. again and tributyltin chloride (1.67 mmol, 0.45 ml) was added to the reaction mixture. The reaction was then stirred at room temperature overnight and water was added to quench the reaction. Dichloromethane was used to extract the product in a separatory funnel three times and the organic phase was further washed with brine. All the organic layers were combined and dried with magnesium sulfate. The solvent was removed by rotary evaporation and the crude product was used without further purification assuming 67% conversion.

tert-butyl (2-(5′″-fluoro-3′″,4′-dimethyl-[2,2′:5′,2″:5″,2′″-quaterthiophen]-5-yl)ethyl)carbamate Tributyl(5″-fluoro-3,3″-dimethyl-[2,2′:5′,2″-terthiophen]-5-yl)stannane (5, 0.89 g, 1.52 mmol), tert-butyl (2-(5-bromothiophen-2-yl)ethyl)carbamate (6, 0.31 g, 1.0 mmol), tris(dibenzylideneacetone)-dipalladium(0) (27.8 mg, 0.030 mmol, 2%) and tri(o-tolyl)phosphine (37 mg, 0.12 mmol, 8%) was mixed and then degassed three time via Schlenk tube. 15.3 ml dry toluene was added via syringe and the mixture was stirred overnight at 100° C. After the reaction was cooled to room temperature, water was added. Dichloromethane was used to extract the product in a separatory funnel three times and the organic phase was further washed with brine. All the organic layers were combined and dried with magnesium sulfate. After filtration, the solvent was removed by rotary evaporation and the crude product was further purified by silica column with hexane and ethyl acetate in 5:1 ratio. In the end, 0.35 g of light-yellow solid was obtained in a yield of 65%. 1H NMR (400 MHz, CDCl3) δ 7.05 (d, J=3.8 Hz, 1H), 6.98 (dd, J=3.7, 2.4 Hz, 2H), 6.90 (s, 1H), 6.73 (dt, J=3.6, 0.9 Hz, 1H), 6.30 (d, J=2.3 Hz, 1H), 4.68 (s, 1H), 3.41 (d, J=6.8 Hz, 2H), 2.99 (s, 1H), 2.35 (d, J=27.6 Hz, 5H), 1.45 (s, 9H).

### 2-(5′″-fluoro-3′″,4′-dimethyl-[2,2′:5′,2″:5″,2′″-quaterthiophen]-5-yl)ethan-1-aminium iodide (F4TmI)

To a solution of (180 mg, 0.35 mmol) in 10 ml ethanol was added hydroiodic acid (57 wt %, 0.09 ml, 0.7 mmol) and the reaction mixture was stirred at 70° C. for 3 hours with argon flow. After the reaction was completed, the solvent was partially removed until yellow solids precipitate out. Diethyl ether was added to the mixture to further precipitate out the yellow solid. The mixture was sonicated for 5 minutes, filtered, and washed with diethyl ether. Finally, 157 mg of pure F4Tm was obtained in a yield of 83%. 1H NMR (400 MHz, DMSO) δ 7.79 (s, 3H), 7.44-7.06 (m, 4H), 6.96 (d, J=3.6 Hz, 1H), 6.71 (d, J=2.6 Hz, 1H), 3.08 (s, 4H), 2.37 (s, 3H), 2.30 (s, 3H). 13C NMR (101 MHz, DMSO) δ 139.21, 135.51, 135.40, 135.00, 134.59, 134.34, 131.75, 128.51, 127.85, 127.21, 126.48, 124.63, 118.86, 113.03, 112.94, 27.79, 16.00, 15.77. HR-MS (ESI) Expected 420.0379 [M−I]+ Observed 420.0363.

### 5-chloro-3,3″-dimethyl-2,2′:5′,2″-terthiophene

To a solution of 3 (3.62 mmol, lg) dissolved in 50 ml chloroform and 50 ml acetic acid, N-chlorosuccinimide (NCS, 3.8 mmol, 0.5 g) was added to the reaction mixture. The reaction was then stirred at room temperature for 71 hours. Dichloromethane was used to extract the product in a separatory funnel three times and the organic phase was further washed with brine. All the organic layers were combined and dried with magnesium sulfate. The solvent was removed by rotary evaporation and the crude product was further purified by column chromatography with pure hexane. 0.57 g yellow solid was obtained in a yield of 50%. 1H NMR (400 MHz, CDCl3) δ 7.15 (d, J=5.1 Hz, 1H), 7.06 (d, J=3.8 Hz, 1H), 7.01 (d, J=3.8 Hz, 1H), 6.91-6.84 (m, 1H), 6.74-6.69 (m, 1H), 2.41 (s, 3H), 2.34 (s, 3H).

### (5″-chloro-3,3″-dimethyl-[2,2′:5′,2″-terthiophen]-5-yl)trimethylstannane

To a solution of (1.64 mmol, 510 mg) dissolved in 17 ml dry THF, 2.0 M lithium diisopropylamide in hexane (1.80 mmol, 0.9 ml) was added dropwise via syringe at 0° C. in ice bath. Then the ice bath was removed, and the mixture was stirred for 1.5 hour during warm up. The mixture was then cooled to 0° C. again and trimethyltin chloride (1 M, 1.80 mmol, 1.8 ml) was added to the reaction mixture. The reaction was then stirred at room temperature overnight and water was added to quench the reaction. Dichloromethane was used to extract the product in a separatory funnel three times and the organic phase was further washed with brine. All the organic layers were combined and dried with magnesium sulfate. The solvent was removed by rotary evaporation and the crude product was used without further purification assuming 70% conversion.

Tert-butyl (2-(5′″-chloro-3′″,4′-dimethyl-[2,2′:5′,2″:5″,2′″-quaterthiophen]-5-yl)ethyl)carbamate (5″-chloro-3,3″-dimethyl-[2,2′:5′,2″-terthiophen]-5-yl)trimethylstannane (0.78 g, 1.64 mmol), tert-butyl (2-(5-bromothiophen-2-yl)ethyl)carbamate (0.35 g, 1.15 mmol), tris(dibenzylideneacetone)-dipalladium(0) (30 mg, 0.033 mmol, 2%) and tri(o-tolyl)phosphine (40 mg, 0.13 mmol, 8%) was mixed and then degassed three time via Schlenk tube. 16 ml dry toluene was added via syringe and the mixture was stirred overnight at 100° C. After the reaction was cooled to room temperature, water was added. Dichloromethane was used to extract the product in a separatory funnel three times and the organic phase was further washed with brine. All the organic layers were combined and dried with magnesium sulfate. After filtration, the solvent was removed by rotary evaporation and the crude product was further purified by silica column with hexane and ethyl acetate in 5:1 ratio. In the end, 0.28 g of light-yellow solid was obtained in a yield of 46%. 1H NMR (400 MHz, CDCl3) δ 7.07 (d, J=3.8 Hz, 1H), 7.00 (dd, J=10.5, 3.7 Hz, 2H), 6.91 (s, 1H), 6.75-6.70 (m, 2H), 4.68 (s, 1H), 3.41 (d, J=6.8 Hz, 2H), 2.99 (t, J=6.7 Hz, 2H), 2.37 (d, J=17.8 Hz, 6H), 1.45 (s, 9H). 2-(5′″-chloro-3′″,4′-dimethyl-[2,2′:5′,2″:5″,2′″-quaterthiophen]-5-yl)ethan-1-aminium iodide.

### (Cl4TmI)

To a solution of (167 mg, 0.31 mmol) in 7 ml ethanol was added hydroiodic acid (57 wt %, 0.08 ml, 0.6 mmol) and the reaction mixture was stirred at 77° C. for 3 hours with argon flow. After the reaction was completed, the solvent was partially removed until yellow solids precipitate out. Diethyl ether was added to the mixture to further precipitate out the yellow solid. The mixture was sonicated for 5 minutes, filtered, and washed with diethyl ether. Finally, 162 mg of pure Cl4TmI was obtained in a yield of 92%. 1H NMR (400 MHz, DMSO) δ 7.74 (s, 3H), 7.27-7.20 (m, 3H), 7.17 (s, 1H), 7.08 (s, 1H), 6.96 (d, J=3.7 Hz, 1H), 3.16-2.94 (m, 4H), 2.37 (s, 3H), 2.33 (s, 3H). 13C NMR (101 MHz, DMSO) δ 139.24, 135.78, 135.64, 134.98, 134.51, 134.45, 134.14, 131.73, 129.07, 128.61, 128.53, 127.86, 127.34, 126.56, 126.39, 124.66, 27.79, 15.78, 15.64. HR-MS (ESI) Expected 436.0089 [M−I]+ Observed 436.0077

To understand the relationship between crystal structures and the electronic properties, we applied time-resolved microwave conductivity (TRMC) measurements to characterize the out-of-plane carrier transport in 2D perovskite thin films (FIG. 2E). (Br4Tm)2PbI4 sample possesses the highest yield-mobility product, which is a factor of 2 to 4 larger than that of (Cl4Tm)2PbI4 and (4Tm)2PbI4. However, the (F4Tm)2PbI4 sample exhibits significantly lower mobility, which could be correlated with the difficulty of achieving high quality (F4Tm)2PbI4 single crystal and the repulsion between fluorine atoms. We also performed conductive atomic force microscope (cAFM) to examine the spatial distribution of the current path in these thin films (FIG. 2F). In agreement with the TRMC results, (F4Tm)2PbI4 sample exhibits the lowest conductivity, while (Br4Tm)2PbI4 sample preserves the highest conductivity. The higher out-of-plane conductivity of (Br4Tm)2PbI4 thin film than Cl4TmI sample has also been confirmed with single crystal conductivity (FIG. S6). The single crystal structures show that the outer thiophenes in (Cl4Tm)2PbI4 crystals favor in-plane edge-to-edge arrangement between the neighboring Cl4Tm layers, similar to 4Tm samples, which may not support efficient charge transfer (FIG. S7). In contrast, the (Br4Tm)2PbI4 crystal exhibits face-to-face ligand packing geometry, thus exhibiting higher out-of-plane conductivity. However, the cAFM images reveal that (Br4Tm)2PbI4 thin film, although possessing higher conductivity, has greater heterogeneity in the current path distribution, which may result from the non-uniform crystallinity and the potential higher formation energy of this 2D structure.

### 2D/3D Heterostructures Formation and Characterization

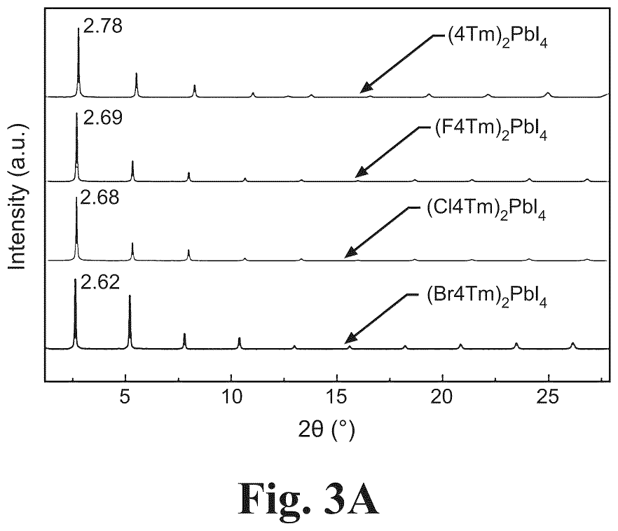

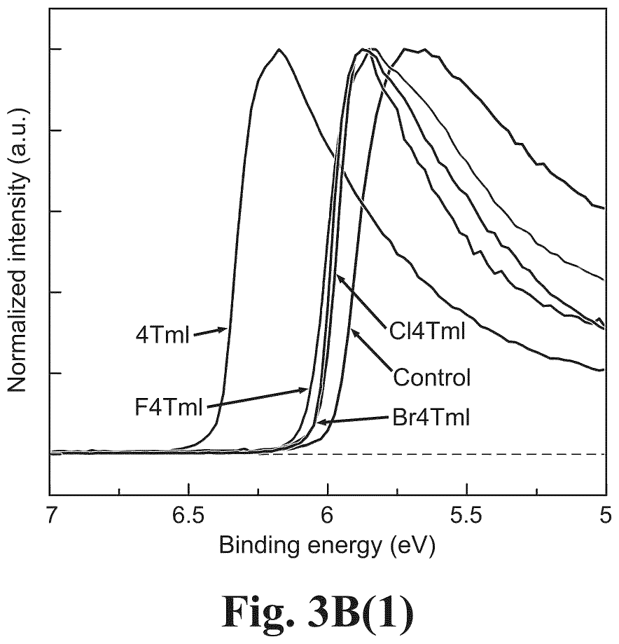

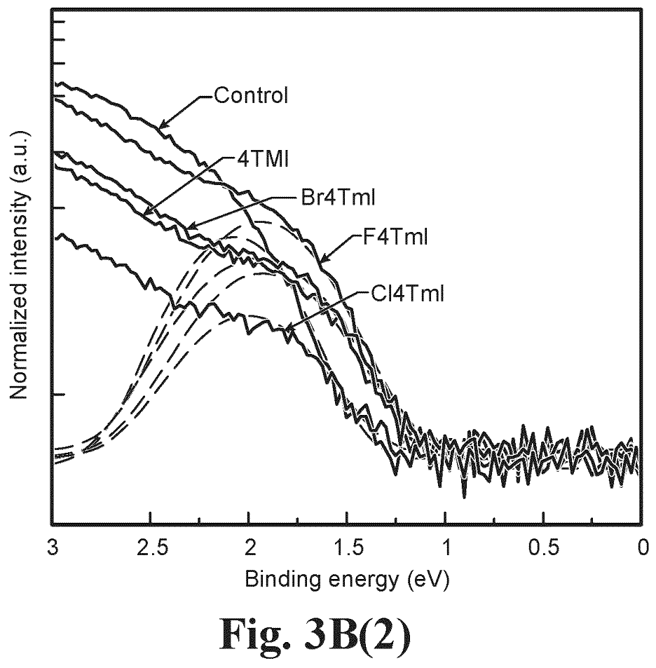

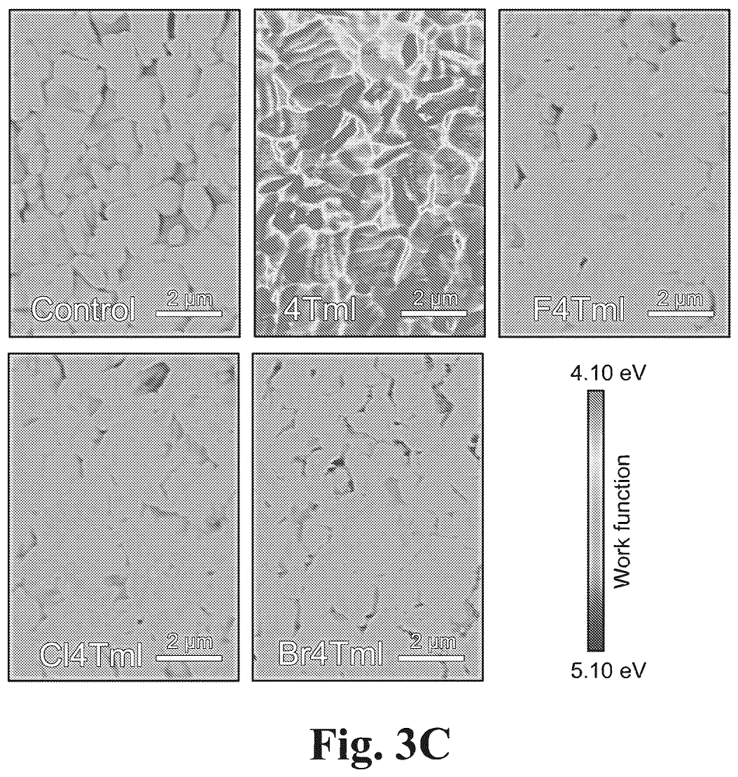

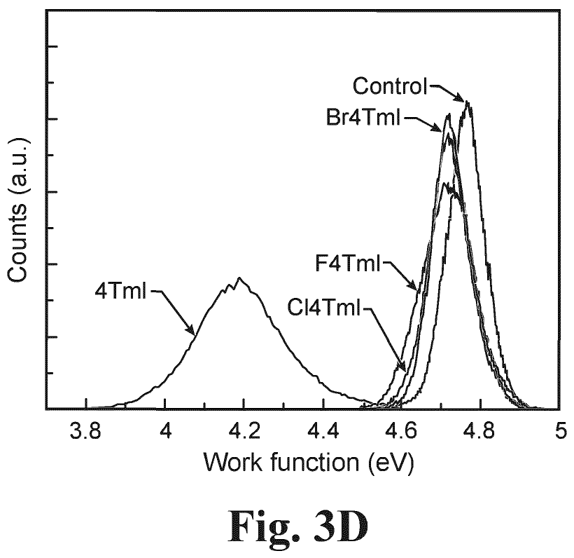

The formation of 2D/3D heterostructures on the surface of 3D perovskites was then investigated for photovoltaic devices. The 2D structures were formed by means of coating the corresponding ligand solution on the surface of 3D perovskite, followed by thermal annealing. To enhance the 2D perovskite signal for XRD characterization, we extended the reaction time between 3D perovskite and the ligands by dropping the ligand solutions and waiting for 60 s before spinning. The thin-film XRD suggests that n=1 2D structures form with all the investigated ligands, as evidenced by the diffraction peaks at low angles (<10°) (FIG. 3A), which match with the peaks from pure 2D perovskite thin films. Only the n=1 phase is formed on the surface with horizontal orientation, while high-n-number phases are absent for all ligands investigated. We ascribe the stability of 2D structures, the rigidity of the ligands, and their unlikely penetration into the 3D structure due to steric bulk, all as factors that prevent formation of other phases during the treatment. The exclusive formation of n=1 phase in 2D/3D junctions distinguishes these ligands from conventional small ligands and eliminates the influence of phase-impurity in the surface characterizations. The AFM images indicate the unchanged surface morphology of perovskite with short-time ligand treatment. The X-ray photoelectron spectroscopy (XPS) conducted on ligand-treated 3D perovskite thin films clearly demonstrates the existence of oligothiophene ligands on the 3D perovskite surface from the peaks of S 2p at 164 eV. Moreover, the characteristic peaks of F is (687 eV), Cl 2p (202 eV) and Br 3d (71 eV) show up in the XPS results of F4TmI-, Cl4TmI- and Br4TmI-thin films, respectively, which belong to the terminal substituents of the corresponding ligands.

The surface potential and 2D/3D band alignment may be modulated via rational design of ligand molecular configurations. Through ultraviolet photoelectron spectroscopy (UPS) measurements (FIG. 3B), we verified that ligand treatment upshifts the VBM in comparing with the control film (untreated), based on the aligned Fermi level, which is induced by the shallower HOMO levels of the conjugated ligands. The upshifted VBM generates a more p-type surface, which is expected to facilitate efficient hole transfer from perovskite to PTAA (with a reported HOMO at −5.2 eV) (19). The shallow HOMO levels of these conjugated ligands also allow them to directly extract holes from 3D perovskites, which is verified by the time-resolved photoluminescence (TRPL) measurement with a bi-exponential decay and fast hole extraction process within 20 ns.

The work functions (WFs) have also been extracted from UPS measurements, which show notable differences between 4TmI and halogen-4TmI treatment. The 4TmI treatment significantly reduces WF to 3.82 eV from the 4.22 eV of the control film. In contrast, the reduction of WF is smaller when halogen-substitutions are introduced, showing less than 0.1 eV changes (FIG. 3B). Kelvin probe force microscopy (KPFM) measurements revealed WF distribution differences at the ligand-treated surfaces (FIG. 3C). The average WF of 4TmI-treated surface reduced to 4.18 eV from 4.76 eV for the control film, while the change of WF of halogen-4TmI treated surface was negligible (FIG. 3D), which is in accordance with the trend observed in UPS analysis.

The band alignment formed with 4TmI surface treatment showed that the perovskite surface has shallower VBM compared with the bulk material, but a negative AWF could generate a potential well at the interface of 2D/3D heterostructure and trap the electrons. Unlike the downshifted VBM of other 2D/3D heterostructures formed with wide-bandgap ligands, the hole transfer benefits from the upshifted VBM of perovskite surface with conjugated ligands. However, the trapped and accumulated electrons at perovskite/HTL interface can cause charge-trapping induced defects. In comparison, the 2D/3D heterostructures formed with halogen-4TmI cause minimum WF shift, thus being unlikely to create a deep potential well at interfaces. The reduced charge-trapping defects in halogen-4TmI treated films are evidenced by the enhanced PL intensities with a film structure of glass/3D perovskite/2D perovskite. The reduced bimolecular recombination was further affirmed with intensity-dependent photoconductivity transient characterization from TRMC measurements.

In addition, benefitted from the exceptional out-of-plane transport of the n=1 2D perovskite structures containing Cl4TmI and Br4TmI, the coverage of 2D perovskite atop of 3D thin films does not decrease the carrier mobility, which further indicates that the enhanced out-of-plane charge transport in 2D perovskites is critical to reduce charge transfer barriers at the 2D/3D heterojunction. The cAFM results even suggest slightly higher conductivity in Cl4TmI-treated films than that in Br4TmI samples, which is attributed to the different formation energy of 2D/3D heterojunction with different ligands.

### Carrier Dynamics and Device Performance

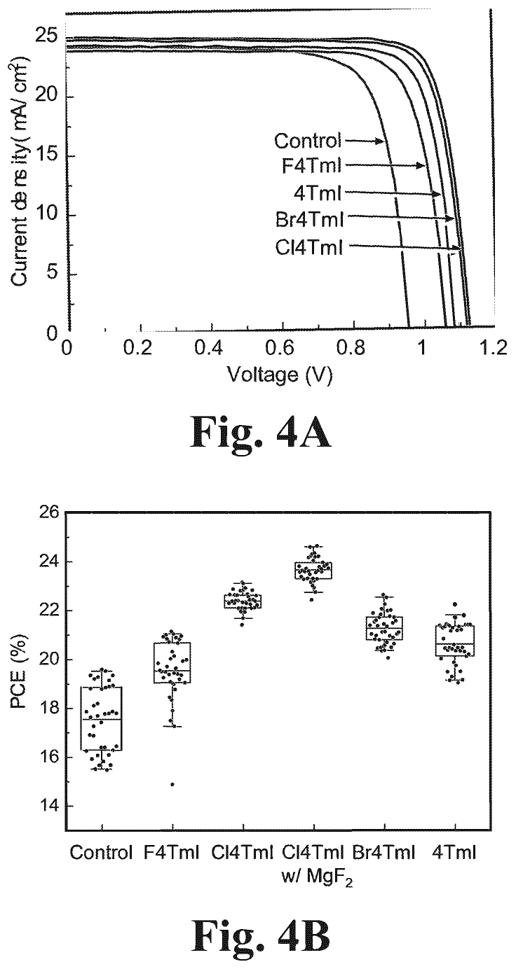

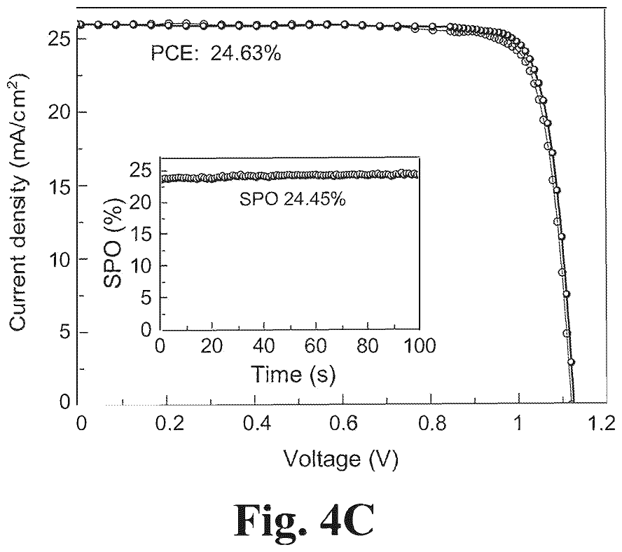

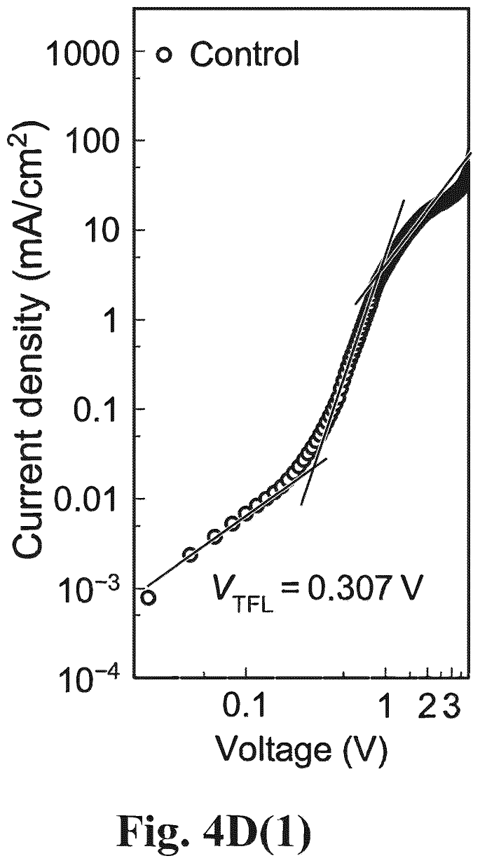

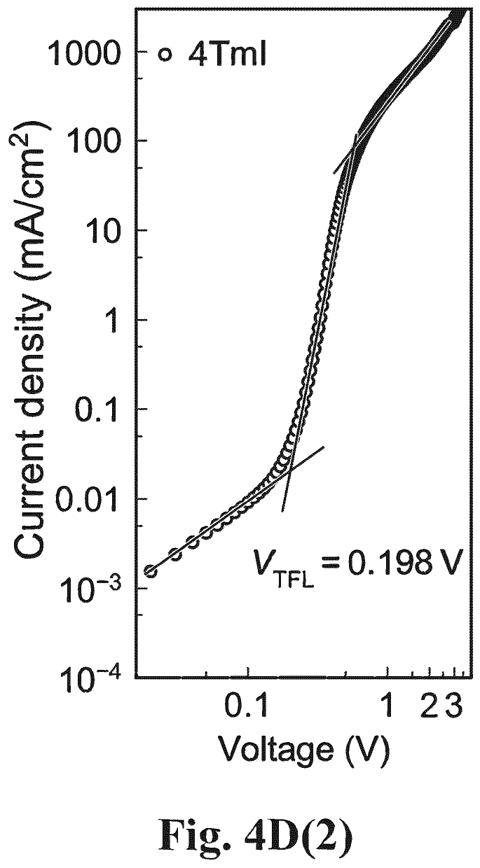

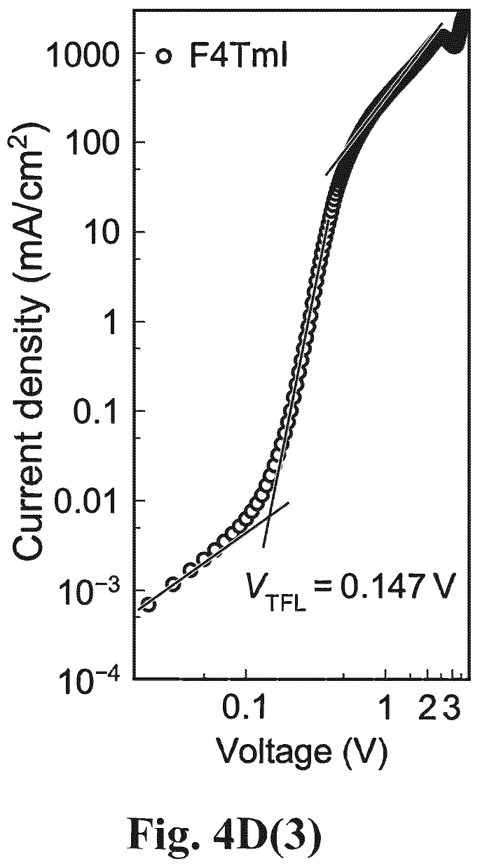

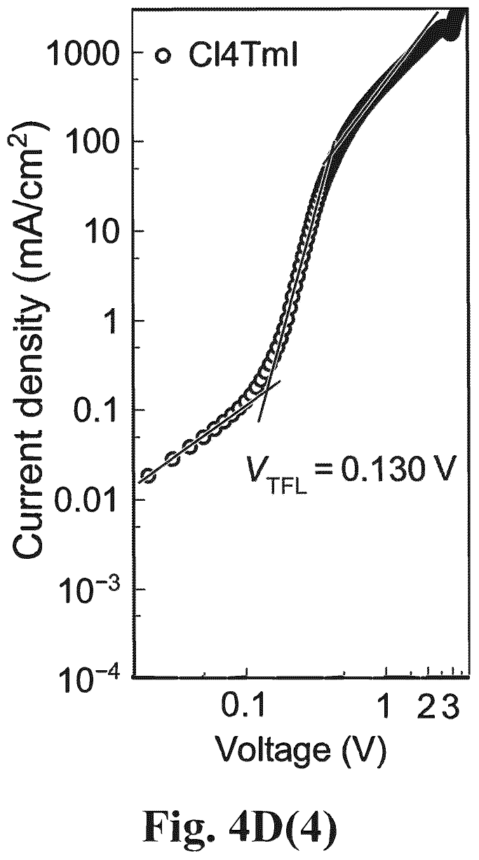

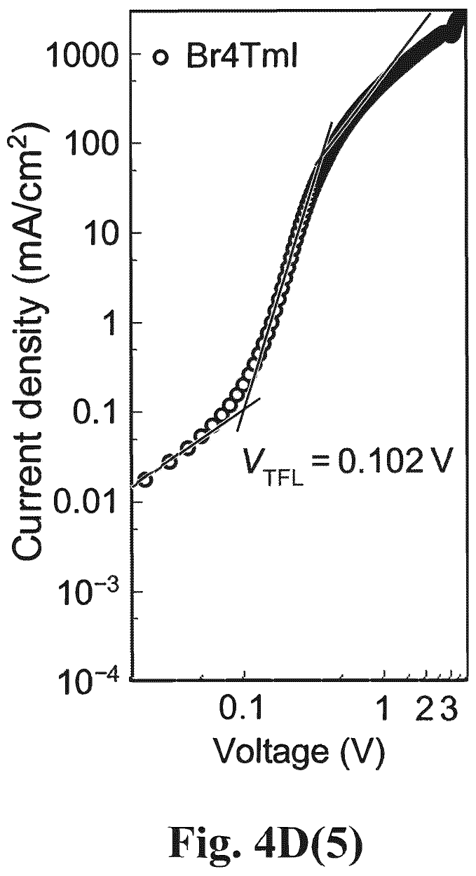

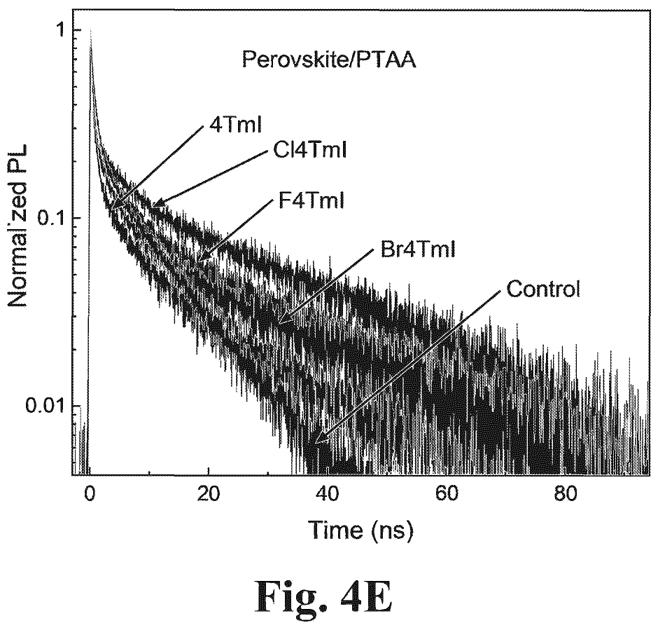

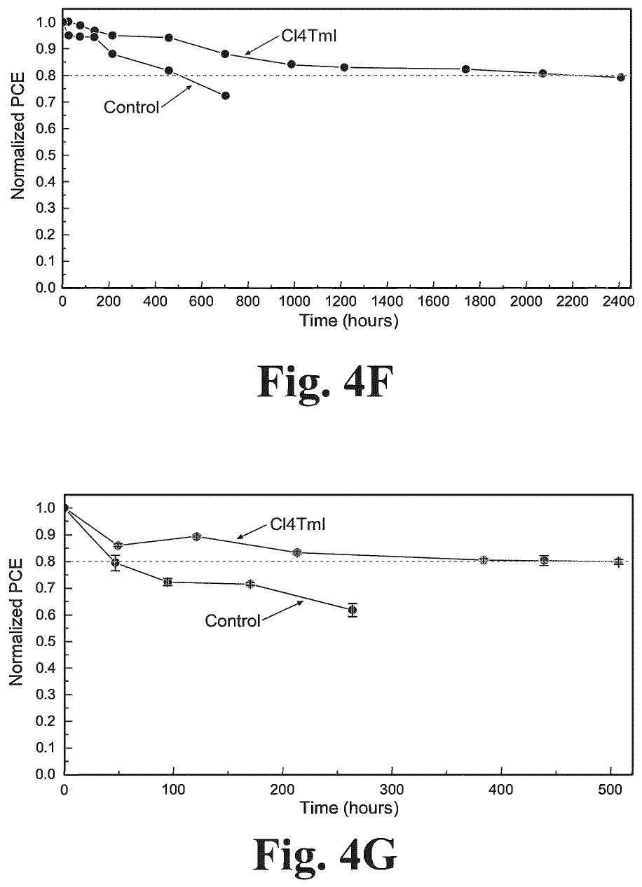

The impact of these 2D/3D heterostructures on the photovoltaic performance was investigated by fabricating the PSCs using an n-i-p device architecture, ITO/SnO2/perovskite/PTAA/Au, with different surface ligand treatments. Some exemplary perovskite materials that may be used to make photovoltaic devices include ABC perovskites, wherein A and B are cations and C is an anion, with A being Cs, FA, MA or the like and B being Pb, Sn, or the like, and C being I, Br, or the like—for example CsₓMA_{y}FA_{1-x-y}Pb(I_{1-z}Br_{z})₃, MAPbI₃, FAPbI₃, and the like, wherein MA is methylammonium and FA is formamidinium. In agreement with prediction, the Cl4TmI and Br4TmI surface treatment results in significantly enhanced PCE, which outperformed the devices treated with 4TmI and F4TmI. A typical set of J-V curves of devices fabricated with different ligands is shown in FIG. 4A. The non-ideal energy alignment of 4TmI, and the unstable 2D crystal structure and low conductivity of (F4Tm)2PbI4 are the limiting factors of these two ligands. Comparing with Cl4TmI, slightly less improvement with Br4TmI treatment was achieved, which could correspond to the different conductivity of 2D/3D heterostructure formed with Cl4TmI and Br4TmI, and the heterogeneity of conductivity distribution in (Br4Tm)2PbI4 thin film. To verify the reproducibility of the results, we provide the statistics for at least 20 devices of each condition (FIG. 4B). Furthermore, we compared our conjugated ligands to the devices passivated with butylammonium iodide and phenethylammonium iodide. Neither of these commonly used ligands were able to produce comparable PCEs as Cl4TmI and Br4TmI, which suggests the critical role of the semiconducting ligands in 2D/3D heterostructures. In addition to the FA0.9MA0.05Cs0.05PbI3 perovskite composition, we also investigated the effect of Cl4TmI surface treatment on PSCs with a composition of double halide (FA_{0.88}MA_{0.07}Cs_{0.05}PbI_{2.89}Br_{0.11}) and also found an increase in PCE.

The focus was on PTAA as hole transporting layer because it is considered as a more stable hole transporting material than Spiro-OMeTAD and does not need lithium salt for efficient doping, which eliminates a degrading factor of FAPbI₃. In addition, PTAA is known to be less sensitive to processing conditions with no air-aging requirement and leads to devices with better reproducibility. However, the limiting factor of the application of PTAA is the interface quality with perovskite, leading to low PCE values in conventional devices. Here, the designed conjugated ligands increase the hydrophobicity of perovskite surface, forming perfect atomic registry to the perovskite lattice, and share similar aromaticity and improve the interface contact between perovskite and PTAA. This critical interface supports efficient hole transfer and results in increased open circuit voltage (VOC) and fill factor (FF). With further optimization of ligand passivation and anti-reflection layer coating, a champion device with a PCE of 24.63% was achieved through Cl4TmI treatment (VOC=1.125 V, FF=84.32%, JSC=25.96 mA/cm²) with small hysteresis (FIG. 4C), which is the highest reported PCE among PTAA-based PSCs to the best of our knowledge. A stabilized power output of 24.45% was also measured at maximum power point (FIG. 4C), and the external quantum efficiency (EQE) spectrum was confirmed with an integrated JSC of 25.5 mA/cm². The reproducibility of our strategy has also been demonstrated by showing the small deviation from person-to-person variations of four different researchers.

Space-charge-limited current (SCLC) was used to probe the hole mobilities in the hole-only devices (FIG. 4D). Devices treated with different conjugated ligands all exhibit almost two orders of magnitude increase in hole mobility compared with the control device, which highlights the critical role of interface treatment in charge transport efficiency. It is noteworthy that, although the F4TmI-treated perovskite thin film exhibits lower mobility than the control film by TRMC, the F4TmI-device still shows higher hole mobility than the control device, further supporting the notion that PTAA/perovskite interface is the major bottleneck at the device level. In addition, the trap densities extracted from the trap-filled limit voltage (VTFL) in SCLC plots indicate reduced defect density in ligand-treated devices. TRPL measurements on samples with a structure of glass/perovskite/ligand/PTAA were used to assess the defect densities at interfaces and the charge extraction processes (FIG. 4E). Ligand-treated films benefit from the gradient energy level alignment, exhibiting faster charge extraction, as indicated by the fast decay of PL at initial stage. In the second stage of the bi-exponential decay, the PL lifetime is dominated by defect-induced charge recombination. The lifetime of Cl4TmI-treated perovskite is 20.65 ns, two times higher than the 9.34 ns of the control sample. The suppressed mobile ions in Cl4TmI-treated devices were further evidenced by the capacitance-frequency profiles of the device compared with the control device. The decreased capacitance at low frequency region (<100 Hz) in the Cl4TmI-treated device reveals less mobile ion response, which is correlated with the suppressed defect density at surface. The tuned energy level alignment of perovskite surface not only results in efficient charge transfer, but also affects the built-in potential (Vbi). The Mott-Schottky plot analysis of ligand-treated devices reveals higher Vbi compared with that of control device, among which Cl4TmI device exhibits the highest Vbi. In addition, the improved energy level alignment also reduces the energy barriers for charge injection when the device is operated as an LED, and results in an electroluminescence EQE of 4.6%.

Lastly, the thermal stability of the unencapsulated devices at 65° C. was tracked in a N₂ environment (FIG. 4F). The device treated with Cl4TmI maintained 80% of its initial efficiency after 2220 hours of heating, while the PCE of control device dropped by 20% within 640 hours, showing only one third of T80 lifetime compared with the Cl4TmI-treated device. The photostability of the encapsulated device under continuous illumination was checked at open-circuit condition in N2 environment (FIG. 4G). The photogenerated charge carriers are unextractable at open-circuit condition, and can accumulate at interfaces, accelerating the degradation process. The Cl4TmI-treated device exhibits 20% relative efficiency drop after 507 hours while the control device decreased to 80% of its initial efficiency within 50 hours. In addition, the Cl4TmI-treated device maintained 80% of its initial PCE after 496 hours of continuous operation under illumination using maximum power point (MPP) tracking in N2 environment with temperature around 45° C. These results suggest the important role of organic molecular design in holistically manipulating the physical as well as energy landscapes to reduce charge transfer barriers and defects at 3D/2D/HTL heterointerfaces. Importantly, this strategy is generically applicable to multiple small molecular and polymeric HTL materials with significantly improved performance, representing a critical design element for future PSC interfacial engineering.

### EXAMPLES

### 2D Perovskite Single Crystal Growth

(Cl4Tm)2PbI4 single crystal was obtained by slow cooling method. 2 mg of Cl4TmI, 5 mg PbI2, 200 μl 57 wt % HI solution, 100 μl H3PO2 was added to 1 ml ethanol. The mixture was heated at 100° C. until dissolved and then the solution was slowly cooled to room temperature over the course of 60 hours. By filtration and ethanol wash, orange needle-like single crystals was collected.

(Br4Tm)2PbI4 single crystal was obtained by solvent diffusion method. 0.005 M Br4TmI and 0.01 M PbI2 were dissolved in gamma-butyrolactone (GBL) at 70° C. overnight. After dissolution, 0.1 ml of the precursor solution in a small vial was placed in a large vial with 3 ml chloroform as antisolvent. Orange plate-like crystals precipitated out after 3 days. The crystallization process was conducted at room temperature in atmosphere.

### 2D Perovskite Film Fabrication

Glass slides were cleaned by soap water, water, acetone, isopropanol for 15 min in ultrasonic bath, dried with nitrogen gun and then were used as substrates for 2D perovskite thin film fabrication. The clean substrates were treated with UVO for 20 min before use. The precursor solution (200 l) for spin-coating was prepared by dissolving 0.2 M ligands and 0.1 M PbI2 in dry DMF/DMSO (in 4/1 ratio) at 70° C. For spin-coating, 20 μl of precursor solution was used with spin speed at 2000 r.p.m. for 30 s. In the end, as-prepared thin films were transfer to a heating plate to anneal at 100˜200° C. for 10 min. The above precursor solution preparation, spin-coating and thermal annealing processes were conducted in a N2 glove box.

### Perovskite Solar Cell Fabrication

The ITO/glass substrates were cleaned extensively with deionized water, acetone and isopropanol. The cleaned substrates were UVO treated for 30 min before using. SnO2 (15% wt.) stock solution was diluted with IPA:H2O (v/v=1:1) to 2.14%, then 0.61% PEIE solution was added to the SnO2 solution. The SnO2 solution was spun coated onto the ITO substrate at 3000 r.p.m, followed by annealing at 150° C. for 30 min. After UVO treating the SnO2 surface for 10 min, 10 mM KOH solution was coated on to the substrate at 3000 r.p.m, followed by another annealing at 150° C. for 30 min. The SnO2 substrates were UVO treated for 10 min before transferred into the glovebox to conduct the following process. The perovskite film was coated on SnO2 substrate with a two-step method. In the first step, the PbI2 solution (PbI2 691.5 mg, CsI 19.5 mg, DMF 900 L, DMSO 100 L) was spun coated onto the substrate at 1500 r.p.m. for 30 s, followed by annealing at 70° C. for 1 min. After cooling down, the cation solution (FAI 90 mg, MAI 5 mg, MACI 10.8 mg, IPA 1 mL) was coated on the PbI2 film at 1500 r.p.m. for 30 s, followed by annealing at 150° C. for 15 min in ambient environment (50-70% RH). For FA0.88MA0.07Cs0.05PbI2.89Br0.11 devices, the composition of cation solution changed to 90 mg FAI, 3.2 mg MABr and 10.8 mg MACI in 1 mL IPA. The perovskite film was then transferred back to N2-filled glovebox for ligand and hole transporting layer coating. The conjugated ligands were dissolved in a mixture of chlorobenzene and isopropanol (9:1 v/v) with a concentration of 0.5 mg/mL. For ligand-treated devices, the ligand solution was coated on perovskite surface at 4000 r.p.m., followed with annealing at 100° C. for 2 min. PTAA hole transporting layer was prepared in 30 mg/mL chlorobenzene solution, doped with 11% TPFB. The doped PTAA solution was stirred at 45° C. overnight. PTAA solution was spun on perovskite film at 4000 r.p.m. for 30 s, followed by annealing at 80° C. for 5 min. Finally, 90 nm gold was evaporated onto the device with shadow mask to determine the device area. For champion devices, 105 nm MgF2 was evaporated onto the glass substrate as anti-reflection layer.

While the present disclosure has been described with reference to certain embodiments, it will be apparent to those of ordinary skill in the art that nigh-infinite other embodiments and implementations are possible that are within the scope of the present disclosure without departing from the spirit and scope of the present disclosure. Accordingly, it should be understood that the disclosure is not limited to any embodiment described herein. It should also be understood that the phraseology and terminology employed above are for the purpose of describing the disclosed embodiments, and do not necessarily serve as limitations to the scope of the disclosure.

What is claimed is:

1. A device comprising:
a three-dimensional (3D) perovskite layer; and
an organic two-dimensional (2D) perovskite layer operationally connected to the 3D perovskite layer and defining a heterojunction interface;
wherein the organic 2D perovskite layer is constructed from a plurality of 2D ligands selected from the group consisting of (F4Tm)₂PbI₄, (Cl4Tm)2PbI₄, (Br4Tm)₂PbI₄, and combinations thereof.

2. The device of claim 1, wherein one end of the organic 2D perovskite layer terminates with a F, Cl, or Br and the other end terminates with an ammonium group.

3. The device of claim 1, which further comprises:
an electrode layer;
a hole transport layer operationally connected to and sandwiched between the electrode layer and the organic 2D perovskite layer;
a substrate layer; and
a tin oxide layer operationally connected to and sandwiched between the substrate layer and the 3D perovskite layer.

4. The device of claim 3, wherein the substrate layer is selected from the group consisting of indium tin oxide and glass.

5. The device of claim 1, wherein the 3D perovskite layer and the organic 2D perovskite layers are thin films.

6. The device of claim 3, wherein the 3D perovskite layer is methylammonium (MA) lead iodide.

7. The device of claim 3, wherein the electrode layer is gold.

8. The device of claim 3, wherein the 3D perovskite layer is an ABC perovskite, wherein A and B are cations and C is an anion, wherein A is selected from the group consisting of Cs, formamidinium (FA), and MA; wherein B is selected from the group consisting of Pb, Sn, and combinations thereof, and wherein C is selected from the group consisting of I, Br, and combinations thereof.

9. A photovoltaic device comprising:
a gold electrode layer;
an organic two-dimensional (2D) perovskite layer constructed from a plurality of 2D ligands selected from the group consisting of (F4Tm)₂PbI₄, (Cl4Tm)₂PbI₄, (Br4Tm)₂PbI₄, and combinations thereof;
a three-dimensional (3D) perovskite layer operationally connected to the organic 2D perovskite layer and defining a heterojunction interface;
a PTAA hole transport layer operationally connected and sandwiched between the electrode layer and the organic 2D perovskite layer;
a substrate; and
a tin oxide layer operationally connected to and sandwiched between the substrate and the 3D perovskite layer.

10. The photovoltaic device of claim 9, wherein the substrate layer is selected from the group consisting of indium tin oxide and glass; wherein the organic 2D ligand is (Cl4Tm)₂PbI₄.

11. A method of making a photovoltaic device, comprising:
a) forming an organic two-dimensional (2D) structure by coating a ligand solution on the surface of a three-dimensional (3D) perovskite to yield a coated 3D perovskite;
b) thermally annealing the coated 3D perovskite to yield an annealed coated 3D perovskite;
c) providing a metallic conducing layer;
d) operationally connecting the annealed coated 3D perovskite and a hole transporting layer, wherein the hole transporting layer is in electric contact with the organic 2D structure;
e) providing a nonconducting substrate; and
f) providing a metal oxide layer operationally connected to the substrate and to the 3D perovskite.

12. The method of claim 11, wherein the hole transporting layer is tin oxide.

13. The method of claim 12, wherein the substrate is selected from the group consisting of indium tin oxide and glass.

14. The method of claim 12, wherein the 2D structure is selected from the group consisting of (F4Tm)₂PbI₄, (Cl4Tm)₂PbI₄, (Br4Tm)₂PbI₄, and combinations thereof.

15. The method of claim 12, wherein the 3D perovskite is a thin film.

16. The method of claim 15, wherein the 3D perovskite is an ABC perovskite, wherein A and B are cations and C is an anion, wherein A is selected from the group consisting of Cs, FA, and MA; wherein B is selected from the group consisting of being Pb, Sn, and combinations thereof, and wherein C is selected from the group consisting of Br, I, and combinations thereof.
